(19) United States
(12) Patent Application Publication
(10) Pub. No.: US 2026/0245841 A1
(43) Pub. Date: Aug. 20, 2026

(54) CONDITIONING METHOD AND PLASMA PROCESSING SYSTEM

(71) Applicant: Tokyo Electron Limited, Tokyo (JP)

(72) Inventors: Toshikatsu TOBANA, Miyagi (JP); Moe SUGAWARA, Miyagi (JP); Atsushi UENO, Miyagi (JP); Takanori BANSE, Miyagi (JP)

(21) Appl. No.: 19/644,449

(22) Filed: Apr. 10, 2026

Related U.S. Application Data
(63) Continuation of application No. PCT/JP2024/036115, filed on Oct. 9, 2024.

(30) Foreign Application Priority Data
Oct. 23, 2023 (JP) 2023-182011

(51) Int. Cl. H01J 37/32

(52) U.S. Cl. CPC H01J 37/32807; H01J 37/3244

(57) ABSTRACT

A method of conditioning a plasma processing chamber, which is configured such that a tungsten-containing gas is supplied into an inside of the plasma processing chamber and plasma processing is applied to a substrate housed in the inside of the plasma processing chamber, the method includes (A) removing moisture from an inside of the plasma processing chamber using a gas free of the tungsten-containing gas, and (B) adjusting an internal environment of the plasma processing chamber by generating plasma while supplying a gas containing the tungsten-containing gas after (A).

### CROSS-REFERENCE TO RELATED APPLICATIONS

This application is a continuation application of International Application No. PCT/JP2024/036115, filed on October 9, 2024, and designated the U.S., which is based upon and claims priority to Japanese Patent Application No. 2023-182011, filed on October 23, 2023. The entire contents of these applications are incorporated herein by reference.

### TECHNICAL FIELD

The present disclosures herein relate to conditioning methods and plasma processing systems.

### BACKGROUND

Patent Literature (PTL) 1 discloses a plasma processing system in which a substrate having a mask film on an upper portion of a pattern is housed in a plasma processing chamber and a tungsten-containing gas is supplied to the plasma processing chamber to form a protective film on the mask film.

In this type of plasma processing system, when performing maintenance to remove a film adhered to components or the like in the plasma processing chamber, for example, a processing vessel is opened to replace consumables, or the inside of the processing vessel is cleaned. When the processing vessel is opened, moisture in the atmosphere is adsorbed on the inside of the processing vessel and parts. In this case, moisture remains in the processing vessel after maintenance. Therefore, the plasma processing apparatus performs processing to remove moisture adhering to the inside of the processing vessel and parts after maintenance.

### CITATION ART

### PATENT LITERATURE

[PTL 1] Japanese Laid-open Patent Application No. 2023‐111329

### SUMMARY OF THE INVENTION

A method of conditioning a plasma processing chamber, which is configured such that a tungsten-containing gas is supplied into an inside of the plasma processing chamber and plasma processing is applied to a substrate housed in the inside of the plasma processing chamber, the method includes (A) removing moisture from an inside of the plasma processing chamber using a gas free of the tungsten-containing gas, and (B) adjusting an internal environment of the plasma processing chamber by generating plasma while supplying a gas containing the tungsten-containing gas after (A).

### BRIEF DESCRIPTION OF THE DRAWINGS

FIG. 1 is a drawing schematically illustrating a plasma processing system according to an embodiment;

FIG. 2 is a schematic diagram illustrating an example of a reaction of a WF gas to a component with moisture attached in a plasma processing chamber;

FIG. 3 is a flowchart illustrating a processing flow of a conditioning method according to the embodiment;

FIG. 4A is a table illustrating processing conditions for a moisture removal process;

FIG. 4B is a table illustrating a relationship between a number of cycles of dry cleaning processing and hydrogen emission intensity remaining in the plasma processing chamber;

FIG. 5A is a table illustrating processing conditions for a seasoning process;

FIG. 5B is a table illustrating the relationship between a number of cycles of seasoning processing and an etching rate of a silicon oxide film performed in a plasma processing chamber 10;

FIG. 6 is a graph illustrating a comparison of flow rates of the WF gas when a flow rate calibration process is performed and when the flow rate calibration process is not performed; and

FIG. 7 is a timing chart illustrating the conditioning method according to the embodiment.

### DESCRIPTION OF THE PREFERRED EMBODIMENTS

In the following, embodiments of the present invention will be described with reference to the accompanying drawings. In the drawings, the same or corresponding constituent elements are denoted with the same reference numerals, and redundant description thereabout may be omitted.

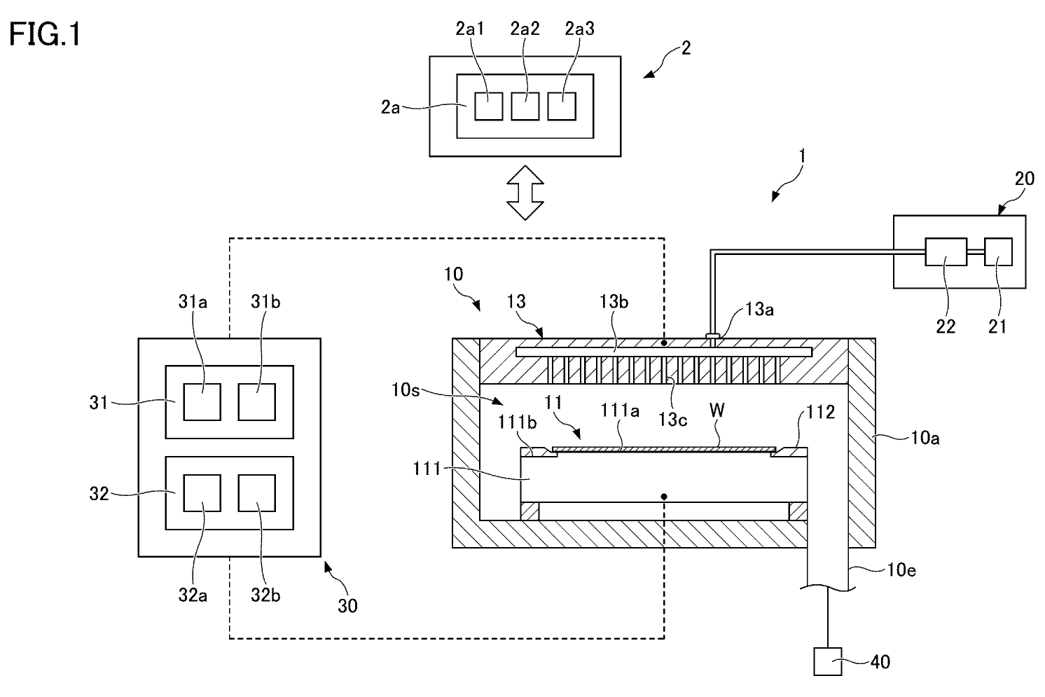

FIG. 1 is a drawing schematically illustrating a plasma processing system according to an embodiment. First, a configuration example of the plasma processing system will be described with reference to FIG. 1.

The plasma processing system includes a capacitively coupled plasma processing apparatus 1 and a controller 2. The capacitively coupled plasma processing apparatus 1 includes a plasma processing chamber 10, a gas supply 20, a power source 30, and an exhaust system 40. The plasma processing apparatus 1 also includes a substrate support 11 and a gas introduction unit. The gas introduction unit is configured to introduce at least one processing gas into the plasma processing chamber 10. The gas inlet includes a showerhead 13. The substrate support 11 is disposed within the plasma processing chamber 10. The showerhead 13 is disposed above the substrate support 11. In one embodiment, the showerhead 13 forms at least a portion of a ceiling of the plasma processing chamber 10. The plasma processing chamber 10 has a plasma processing space 10s defined by the showerhead 13, a lateral wall 10a of the plasma processing chamber 10, and the substrate support 11. The plasma processing chamber 10 has at least one gas supply port for supplying at least one processing gas to the plasma processing space 10s, and at least one gas outlet for exhausting the gas from the plasma processing space. The lateral wall 10a is grounded. The showerhead 13 and the substrate support 11 are electrically isolated from a housing of the plasma processing chamber 10.

The substrate support 11 includes a body 111 and a ring assembly 112. The body 111 has a central region (substrate support surface) 111a for supporting a substrate (wafer) W and an annular region (ring support surface) 111b for supporting the ring assembly 112. The annular region 111b of the body 111 surrounds the central region 111a of the body 111 in plan view. The substrate W is disposed on the central region 111a of the body 111 and the ring assembly 112 is disposed on the annular region 111b of the body 111 to surround the substrate W on the central region 111a of the body 111. In one embodiment, the body 111 includes a base and an electrostatic chuck. The base includes a conductive member. The conductive member of the base functions as a lower electrode. The electrostatic chuck is disposed on the base. The top surface of the electrostatic chuck has the substrate support surface 111a. The ring assembly 112 includes one or more annular members. At least one of the annular members is an edge ring. In addition, although not shown, the substrate support 11 may include a temperature control module configured to regulate at least one of the electrostatic chuck, the ring assembly 112, or the substrate to a target temperature. The temperature control module may include a heater, a heat transfer medium, a flow path, or a combination thereof. A heat transfer fluid such as brine or a gas flows through the flow path. The substrate support 11 may also include a heat transfer gas supply configured to supply heat transfer gas between the back surface of the substrate W and the substrate support surface 111a.

The showerhead 13 is configured to introduce at least one process gas from the gas supply 20 into the plasma processing space 10s. The showerhead 13 has at least one gas supply port 13a, at least one gas diffusion chamber 13b, and a plurality of gas introduction ports 13c. The process gas supplied to the gas supply port 13a passes through the gas diffusion chamber 13b and is introduced into the plasma processing space 10s through the plurality of gas introduction ports 13c. The showerhead 13 also includes a conductive member. The conductive member of the showerhead 13 functions as an upper electrode. In addition to the showerhead 13, the gas inlet may include one or more side gas injectors (SGIs) attached to one or more openings formed in the lateral wall 10a.

The gas supply 20 may include at least one gas source 21 and at least one flow controller 22. In one embodiment, the gas supply 20 is configured to supply at least one process gas from a corresponding gas source 21 to the showerhead 13 via a corresponding flow controller 22. Each flow controller 22 may include, for example, a mass flow controller or a pressure controlled flow controller. In addition, the gas supply 20 may include one or more flow modulation devices that modulate or pulse the flow rate of at least one process gas.

The power source 30 includes an RF power source 31 coupled to the plasma processing chamber 10 via at least one impedance matching circuit. The RF power source 31 is configured to provide at least one RF signal (RF electric power), such as a source RF signal and a bias RF signal, to the conductive members of the substrate support 11 and/or the conductive members of the showerhead 13. Plasma is thereby formed from at least one of the process gases supplied to the plasma processing space 10s. Accordingly, the RF power source 31 may function as at least part of a plasma generator configured to generate plasma from one or more process gases in the plasma processing chamber 10. Also, by providing a bias RF signal to a conductive member of the substrate support 11, a bias potential can be generated in substrate W to draw an ionic component in the formed plasma into substrate W.

In one embodiment, RF power source 31 includes a first RF generator 31a and a second RF generator 31b. The first RF generator 31a is coupled to a conductive member of the substrate support 11 and/or a conductive member of showerhead 13 via at least 1 impedance matching circuit and is configured to generate a source RF signal (source RF power) for plasma generation. In one embodiment, the source RF signal has a frequency in a range of 13 MHz to 150 MHz. In one embodiment, the first RF generator 31a may be configured to generate a plurality of source RF signals having different frequencies. The generated one or more source RF signals are provided to a conductive member of the substrate support 11 and/or a conductive member of the showerhead 13. The second RF generator 31b is coupled to a conductive member of the substrate support 11 via at least one impedance matching circuit and is configured to generate a bias RF signal (bias RF power). In one embodiment, the bias RF signal has a lower frequency than the source RF signal. In one embodiment, the bias RF signal has a frequency in a range of 400 kHz to 13.56 MHz. In one embodiment, the second RF generator 31b may be configured to generate a plurality of bias RF signals having different frequencies. The generated bias RF signal or signals are provided to a conductive member of the substrate support 11. Also, in various embodiments, at least one of the source RF signal or the bias RF signal may be pulsed.

The power source 30 may also include a DC power source 32 coupled to the plasma processing chamber 10. The DC power source 32 includes a first DC generator 32a and a second DC generator 32b. In one embodiment, the first DC generator 32a is connected to a conductive member of the substrate support 11 and is configured to generate a first DC signal. The generated first bias DC signal is applied to the conductive member of the substrate support 11. In one embodiment, the first DC signal may be applied to other electrodes, such as electrodes in an electrostatic chuck. In one embodiment, the second DC generator 32b is connected to a conductive member of the showerhead 13 and is configured to generate a second DC signal. The generated second DC signal is applied to the conductive member of the showerhead 13. In various embodiments, at least one of the first DC signal or the second DC signal may be pulsed. Note that the first and second DC generators 32a, 32b may be provided in addition to the RF power source 31, and the first DC generator 32a may be provided in place of the second RF generator 31b.

The exhaust system 40 may be connected, for example, to a gas outlet 10e provided at the bottom of the plasma processing chamber 10. The exhaust system 40 may include a pressure regulating valve and a vacuum pump. The pressure regulating valve regulates the pressure in the plasma processing space 10s. The vacuum pump may include a turbomolecular pump, a dry pump, or a combination thereof.

The controller 2 processes computer-executable instructions that cause the plasma processing apparatus 1 to perform various types of processing described herein. The controller 2 may be configured to control elements of the plasma processing apparatus 1 to perform various types of processing described herein. In one embodiment, all or part of the controller 2 may be included in the plasma processing apparatus 1. The controller 2 may include, for example, a computer 2a. The computer 2a may include, for example, a processor (CPU: Central Processing Unit) 2a1, a storage 2a2, and a communication interface 2a3. The processor 2a1 may be configured to perform various control operations based on a program stored in the storage 2a2. The storage 2a2 may include RAM (Random Access Memory), ROM (Read Only Memory), HDD (Hard Disk Drive), SSD (Solid State Drive), or a combination thereof. The communication interface 2a3 may communicate with the plasma processing apparatus 1 via a communication line such as a LAN (Local Area Network).

The controller 2 controls each configuration of the plasma processing apparatus 1 to perform plasma processing on the substrate W housed in the plasma processing chamber 10. In the plasma processing system according to the embodiment, a gas for forming a protective film for protecting a mask film on a surface of the substrate W is supplied from the gas supply 20 into the plasma processing chamber 10, and plasma processing for supplying RF electric power from the power source 30 to a conductive member (substrate support 11, showerhead 13) is performed. Thus, plasma etching is performed on the mask film on the surface of the substrate W while forming the protective film.

More specifically, the gas supply 20 supplies a tungsten hexafluoride (WF₆) gas, which is a tungsten-containing gas, as a gas for forming the protective film (hereinafter, the tungsten hexafluoride gas is also referred to simply as a WF gas). The tungsten-containing gas is not limited to the WF gas but may be a gas containing chlorine such as a tungsten pentachloride (WCl₅) gas or a tungsten hexachloride (WCl₆) gas. Further, the additive gas may be supplied together with the WF gas, or it may be supplied at a different timing.-For example, the other additive gas may be a rare gas such as a helium (He) gas or an argon (Ar) gas, an oxygen-containing gas such as an oxygen (O₂) gas or an ozone (O₃) gas, or an inert gas such as a nitrogen (N₂) gas. The controller 2 supplies the tungsten-containing gas as a main gas to the plasma processing space 10s based on the plasma processing conditions set in a recipe and controls plasma generation. Thus, plasma etching can be performed while forming a protective film containing tungsten on the mask film.

As described above, the plasma processing system according to the embodiment performs plasma processing while supplying the tungsten-containing gas (WF gas). Because the WF gas has a higher specific gravity and higher viscosity than other gases, it tends to remain in narrow spaces and is less readily discharged. Therefore, in the plasma processing system using the tungsten-containing gas as the process gas, the plasma processing chamber 10 is opened at the time of maintenance, and components and/or piping inside are cleaned to prevent retention and the like of the WF gas. In this case, moisture (H₂O) in the atmosphere is adsorbed on a component 100 and the like and remains in the plasma processing chamber 10 after maintenance.

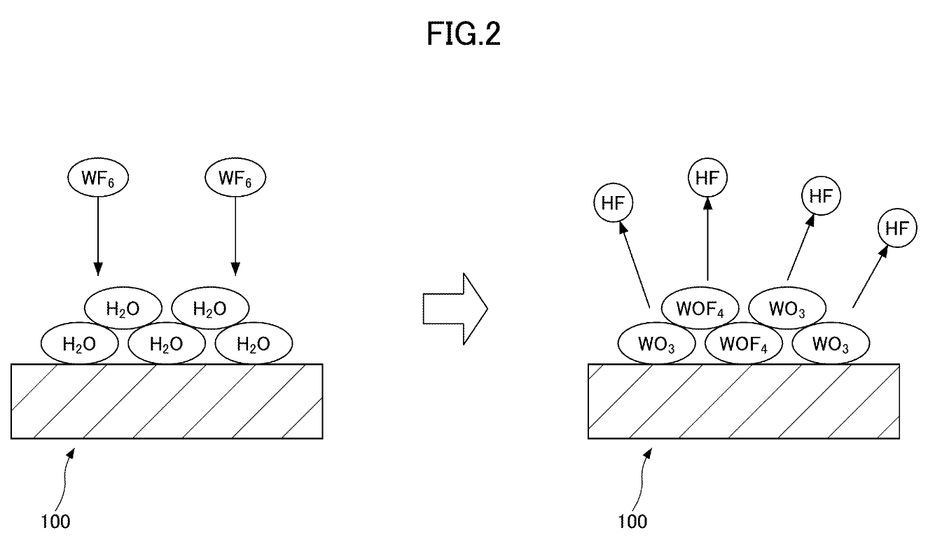

Additionally, the tungsten-containing gas is characterized in that it tends to react with moisture. FIG. 2 is a schematic diagram illustrating an example of a reaction of the WF gas to the component with moisture attached 100 in the plasma processing chamber 10. The WF gas causes reactions with moisture as shown in reaction formulae (1) and (2) below.

WF₆ + 3H₂O → WOF₄ + 2HF ... (1)

WF₆ + 3H₂O → WO₃ + 6HF ... (2)

That is, when the WF gas is supplied in a state where moisture exists in the plasma processing chamber 10, tungsten oxyfluoride (WOF₄) and tungsten oxide (WO₃) are precipitated on the surface of the component 100 in the plasma processing chamber 10. Therefore, in the plasma processing system according to the embodiment, the moisture in the plasma processing chamber 10 is removed first, and then a conditioning method for stabilizing the internal environment for plasma processing of the tungsten-containing gas is executed.

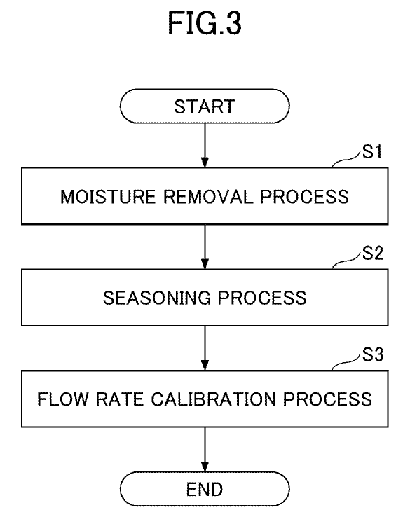

FIG. 3 is a flowchart showing a processing flow of the conditioning method according to the embodiment. The plasma processing system performs a moisture removal process (step S1), a seasoning process (step S2), and a flow rate calibration process (step S3) shown in FIG. 3 as a conditioning method in this order controlled by the controller 2.

The moisture removal process of the conditioning method is a process of removing moisture in the plasma processing chamber 10. In the moisture removal process, for example, while the substrate W is placed on the substrate support 11, a gas for dry cleaning is supplied from the gas supply 20 and an RF source power is supplied from the RF power source 31 to the conductive member to perform plasma processing (dry cleaning). Thus, plasma is generated in the plasma processing space 10s, and moisture and appropriate deposits adhering to the respective components in the plasma processing chamber 10 are removed. The deposits include, for example, deposits of reaction products generated in substrate processing before the dry cleaning processing.

As a gas for dry cleaning, an appropriate gas is preferably selected in accordance with moisture and deposits. However, the tungsten-containing gas is not included in the gas for dry cleaning. A methane tetrafluoride (CF₄) gas, an O₂ gas, and the like are used as the gas for dry cleaning. The CF₄ gas is a CF-containing gas in which carbon (C) and fluorine (F) are bonded and reacts with moisture and deposits to remove them. The O₂ gas can also remove moisture by reacting with moisture.

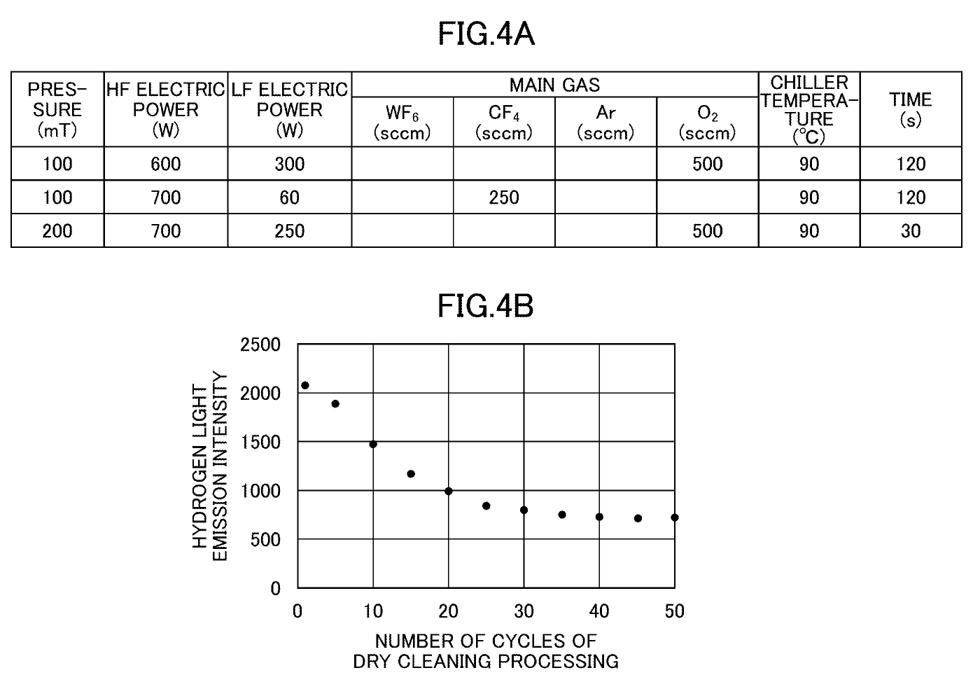

FIG. 4A is a table illustrating processing conditions for a moisture removal process. In the moisture removal process, for example, three steps shown in the table of FIG. 4A are sequentially executed from top to bottom. Specifically, in the first step, the pressure in the plasma processing chamber 10 is set to 100 mT. Further, HF electric power, which is a frequency of 3 MHz to 150 MHz supplied from the RF power source 31, is set to 600 W, and LF electric power, which is a frequency of 400 kHz to 13.56 MHz supplied from the RF power source 31, is set to 300 W. The gas supplied to the main part in the first step is an O₂ gas, and its flow rate is set to 500 sccm. Further, the temperature (chiller temperature) of the heat transfer fluid supplied to the flow path of the temperature control module is set to 90°C. The time for performing the first step is set to 120 seconds.

In the moisture removal process, the second step is performed after first step. In The second step, the pressure in the plasma processing chamber 10 is set to 100 mT, and the chiller temperature is set to 90°C. The HF electric power is set to 700 W, and the LF electric power is set to 60 W. The gas supplied to the main in the second step is CF₄ gas, and its flow rate is set to 250 sccm. The time for performing the second step is set to 120 seconds.

Further, in the moisture removal process, the third step is performed successively after The second step. In The third step, the pressure in the plasma processing chamber 10 is set to 200 mT, and the chiller temperature is set to 90°C. The HF electric power is set to 700 W, and the LF electric power is set to 250 W. The gas supplied to the main in the second step is O₂ gas, and its flow rate is set to 500 sccm. The time for performing the third step is set to 30 seconds.

In the moisture removal process, while the substrate W for the dry cleaning processing is housed in the plasma processing chamber 10, the dry cleaning processing of first to third steps is performed to remove moisture in the plasma processing chamber 10. The substrate W for the dry cleaning processing may be a dummy substrate or the substrate W similar to that for the actual plasma processing.

However, only one cycle of the dry cleaning processing of first to third steps does not sufficiently remove moisture in the plasma processing chamber 10. Therefore, in the moisture removal process, the dry cleaning processing (first to third steps) is repeated a plurality of times to sufficiently remove moisture in the plasma processing chamber 10.

FIG. 4B is a table illustrating a relationship between a number of cycles of dry cleaning processing and hydrogen emission intensity remaining in the plasma processing chamber. The hydrogen emission intensity is an index having a correlation with the amount of hydrogen (in other words, the amount of moisture) in the plasma processing chamber 10. A high hydrogen emission intensity is indicative of a large amount of moisture in the plasma processing chamber 10, whereas a low hydrogen emission intensity is indicative of little moisture in the plasma processing chamber 10.

As shown in FIG. 4B, when the number of cycles of the dry cleaning processing is small, the hydrogen emission intensity is high. As the number of cycles of the dry cleaning processing increases (e.g., to 10, 20, etc.), the hydrogen emission intensity gradually decreases. After the number of cycles of the dry cleaning processing reaches 30, the hydrogen emission intensity becomes almost constant. In this case, almost no moisture remains in the plasma processing chamber 10, indicating that the moisture has been removed. In FIG. 4B, the number of cycles of the dry cleaning processing is increased to 50 and the hydrogen emission intensity is measured in consideration of a margin for more reliably removing moisture and an improvement in throughput until the operation of the plasma processing apparatus 1 is started. From the above, the number of cycles of the dry cleaning processing in the moisture removing process is preferably set in the range of 30 to 50. In the present embodiment, the number of cycles is set to 50.

In the moisture removing process, the plasma processing system may execute waferless dry cleaning processing in which the dry cleaning processing is performed without housing the substrate W in the plasma processing chamber 10. For example, the moisture removal process may incorporate waferless dry cleaning processing between cycles of a dry cleaning process performed with the substrate W housed in the plasma processing chamber 10.

After the moisture removal process, the conditioning method shifts to a seasoning process controlled by the controller 2 (step S2 in FIG. 3). The seasoning process of the conditioning method is a process for adjusting the internal environment in the plasma processing chamber 10 in order to perform the plasma processing by supplying the tungsten-containing gas. The internal environment of the plasma processing chamber 10 is adjusted to be optimal for the new processing conditions. As a result, the etching rate of the plasma processing can be stabilized immediately after the start of the plasma processing.

This seasoning process also adjusts the internal environment in the plasma processing chamber 10 by supplying the seasoning gas by the gas supply 20 and supplying the RF source power from the RF power source 31 to the conductive member with the substrate W mounted on the substrate support 11, for example. In this case, the plasma processing is performed in the plasma processing chamber 10 using the processing conditions (recipe) of the actual substrate processing.

Therefore, the seasoning gas is preferably the same type of gas as that supplied during substrate processing, and the plasma processing apparatus 1 supplies a tungsten-containing gas (WF gas) as the main gas for the seasoning process. The supply amount of the WF gas is preferably greater than the supply amount of the WF gas when the plasma processing apparatus 1 is actually operated (when the substrate W housed in the plasma processing chamber 10 is actually subjected to plasma processing). For example, when the supply amount of the WF gas during operation of the plasma processing apparatus 1 is 5 sccm, the supply amount in the seasoning process is 7 sccm to 12 sccm. Alternatively, seasoning processing may be performed in which only the WF gas and an Ar gas are supplied and other additive gases added during operation of the plasma processing apparatus 1 are not supplied. According to such a seasoning process method, the seasoning processing mainly using the WF gas can be performed in the conditioning method, and the internal environment corresponding to the WF gas can be smoothly stabilized.

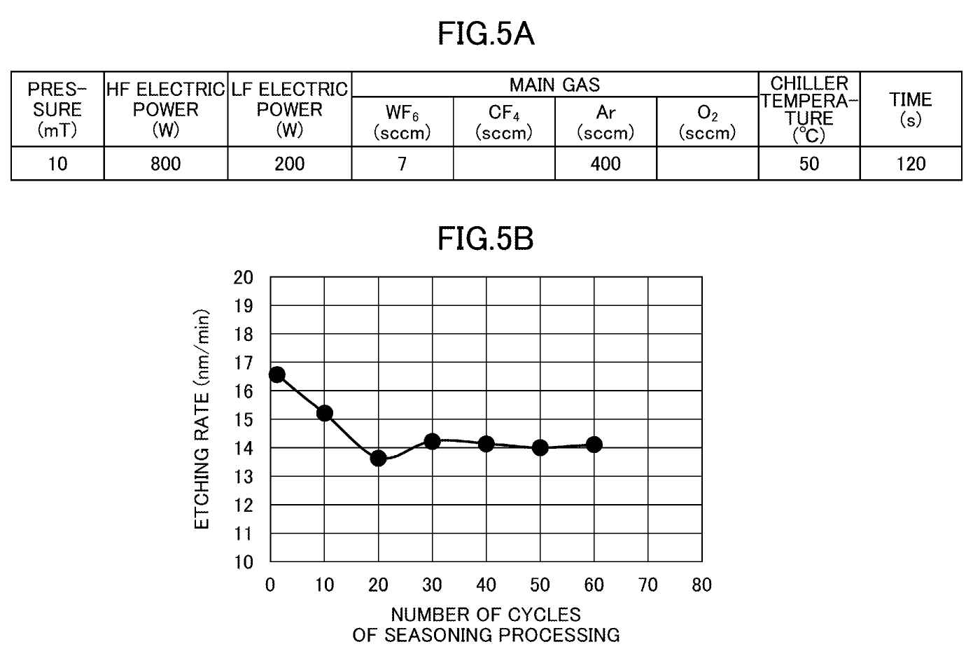

FIG. 5A is a table illustrating processing conditions for the seasoning process. In the seasoning process, the seasoning processing is performed with the processing conditions shown in the table of FIG. 5A as conditions for one cycle. Specifically, in the seasoning processing, the pressure in the plasma processing chamber 10 is set to 10 mT. Further, the HF electric power of the frequency of 3 MHz to 150 MHz supplied from the RF power source 31 is set to 800 W, and the LF electric power of the frequency of 400 kHz to 13.56 MHz supplied from the RF power source 31 is set to 200 W. The gases supplied to the main part in the seasoning processing are the WF gas and the Ar gas, and the flow rate of the WF gas is set to 7 sccm, and the flow rate of the Ar gas is set to 400 sccm. Further, the temperature (chiller temperature) of the heat transfer fluid supplied to the flow path of the temperature control module is set to 50°C. The time for performing the seasoning processing is set to 120 seconds.

By this seasoning process, the internal environment in the plasma processing chamber 10 is adjusted to a state in which substrate processing is performed by the tungsten-containing gas. However, the internal environment in the plasma processing chamber 10 cannot be sufficiently adjusted by performing only one cycle of the seasoning processing. Therefore, also in the seasoning process, the internal environment in the plasma processing chamber 10 is adjusted by repeating a plurality of cycles of the seasoning processing.

FIG. 5B is a table illustrating the relationship between a number of cycles of the seasoning processing and an etching rate of a silicon oxide film performed in the plasma processing chamber 10. The etching rate of the silicon oxide film is an index having a correlation with the internal environment in the plasma processing chamber 10. When the etching rate of the silicon oxide film is high, the internal environment in the plasma processing chamber 10 is unstable, whereas when the etching rate is stable, the internal environment in the plasma processing chamber 10 is regarded as stabilized.

As shown in FIG. 5B, when the number of cycles of the seasoning processing is small, the etching rate of the silicon oxide film is high. As the number of cycles of the seasoning processing increases from 10 to 20, the etching rate gradually decreases. After the number of cycles of the seasoning processing reaches 30, the etching rate becomes approximately constant. In this case, it can be considered that the inside of the plasma processing chamber 10 has been adjusted to an internal environment in which plasma processing is performed by using the WF gas. In FIG. 4B, the etching rate of the silicon oxide film is measured while the number of cycles of the seasoning processing is increased to 60 in consideration of a margin for surely adjusting the internal environment and an improvement in throughput until the operation of the plasma processing apparatus 1 starts. Thus, the number of cycles of the seasoning processing in the seasoning process is preferably set in a range of 30 to 60.

In the present embodiment, the number of cycles is set to 50.

The plasma processing system may incorporate a dry cleaning processing (including waferless dry cleaning processing) at an appropriate timing such as between cycles of the seasoning process. This makes it possible to remove deposits generated in a plurality of times of the seasoning process, for example, and to prevent deposits from remaining in the plasma processing chamber 10.

After the seasoning process, the conditioning method shifts to a flow rate calibration process controlled by the controller 2 (step S3 in FIG. 3). The flow rate calibration process of the conditioning method is a process of calibrating the flow controller 22 for adjusting the flow rate of the WF gas supplied into the plasma processing chamber 10.

For example, in the flow rate calibration process, the plasma processing apparatus 1 flows out the WF gas from the gas source 21 of the gas supply 20, adjusts the WF gas to a target flow rate commanded by the controller 2 in the flow controller 22, and supplies the WF gas into the plasma processing chamber 10. The plasma processing apparatus 1 detects the flow rate of the WF gas in the plasma processing chamber or the flow rate of the WF gas in the exhaust gas, calculates a difference between the actual flow rate determined based on detection information and a target flow rate, and calibrates the flow controller 22.

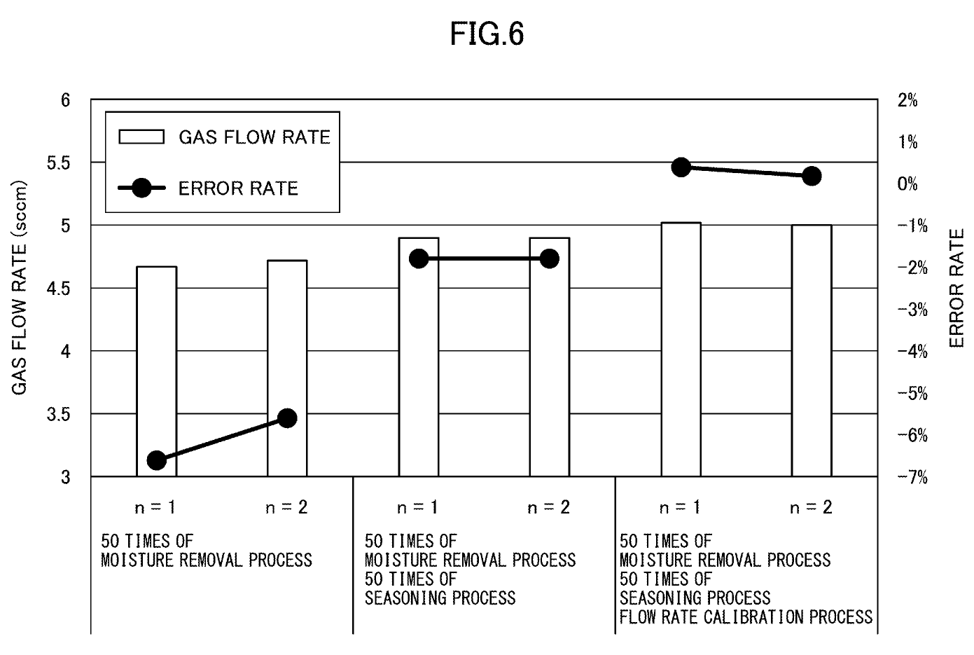

FIG. 6 is a graph illustrating a comparison of flow rates of the WF gas when flow rate calibration process is performed and when the flow rate calibration process is not performed. In FIG. 6, the two bar graphs on the left side show the gas flow rate and error rate when the flow rate of the WF gas was adjusted without performing the flow rate calibration step after performing only the moisture removal process. In FIG. 6, the two bar graphs in the center show the gas flow rate and error rate when the flow rate of the WF gas was adjusted without performing the flow rate calibration step after performing the moisture removal process and the seasoning process. In FIG. 6, the two bar graphs on the right side show the gas flow rate and error rate when the flow rate of the WF gas was adjusted by performing the flow rate calibration step after performing the moisture removal process and the seasoning process. In addition, each of the two bar graphs shows that measurement was performed multiple times (two times) in order to confirm reproducibility of the experiment.

The flow rate of the WF gas when only performing the moisture removal process was approximately 4.6 sccm to 4.7 sccm with respect to the target flow rate of 5 sccm, and the flow rate of the WF gas was not sufficient for the target flow rate. Conversely, the flow rate of the WF gas when both the moisture removal process and the seasoning process were performed was 4.9 sccm, which was sufficiently close to the target flow rate (5 sccm) compared with the flow rate when only the moisture removal process was performed. This indicates that the condition of the WF gas inside the plasma processing chamber 10 could be sufficiently adjusted by performing the seasoning process for supplying the WF gas.

When performing the moisture removal process, the seasoning process, and the flow rate calibration step, the flow rate substantially matched the target flow rate (5 sccm). That is, in the conditioning method, the flow rate calibration step is performed last, so that the flow rate of a WF₆ gas in the flow controller 22 can be properly calibrated. In particular, in the conditioning method, since the seasoning process is performed before the flow rate calibration step, the flow controller 22 is calibrated in a state where the internal environment in the plasma processing chamber 10 is stabilized. Thus, in the conditioning method, the flow controller 22 can be calibrated with higher accuracy. Thus, the plasma processing apparatus 1 can stably supply the WF gas of the target flow rate into the plasma processing chamber 10 during the actual substrate processing.

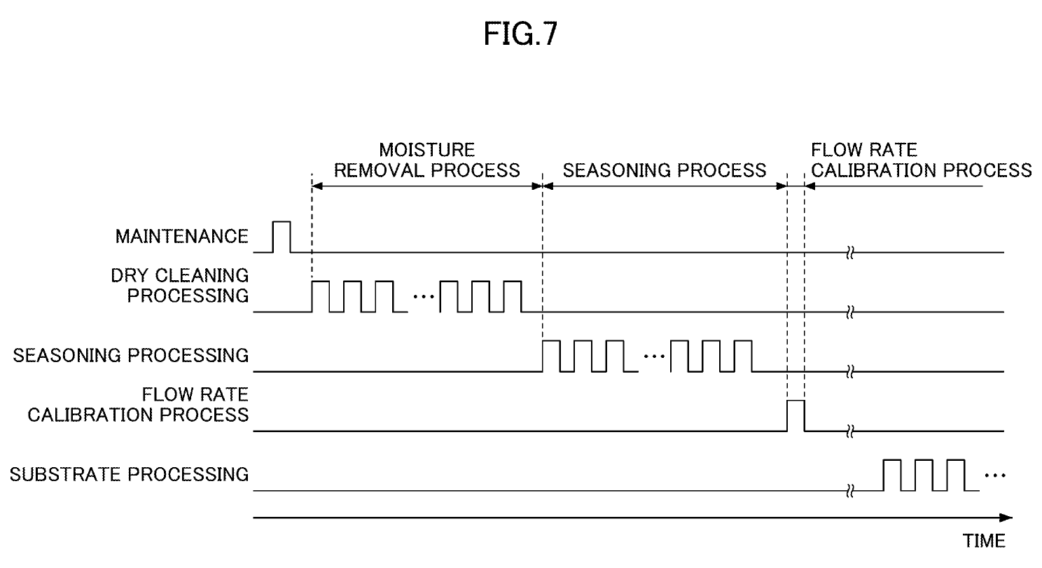

To summarize the conditioning method according to the above embodiments, the conditioning method is performed at the start-up of the apparatus and after the maintenance in a time series as shown in FIG. 7. FIG. 7 is a timing chart illustrating a conditioning method according to the embodiment.

In the conditioning method before the substrate processing to which the tungsten-containing gas is supplied, the plasma processing system repeats the first to third steps of the dry cleaning processing in the moisture removing process (step S1: step (A)) a plurality of times (e.g., 50 cycles). Next, the seasoning treatment in the seasoning process (step S2: step (B)) is repeated a plurality of times (e.g., 50 cycles). Finally, a flow rate calibration step (step S3: step (C)) is performed.

As a result, the plasma processing system can stably supply WF gas during actual substrate processing after the conditioning method is performed, which improves the accuracy of the plasma processing. In particular, since the plasma processing system can precisely adjust the flow rate of the WF gas from the start of the substrate processing, defects at the start of the substrate processing can be greatly reduced.

It should be noted that the conditioning method and the plasma processing system are not limited to the above-described embodiment, and various modifications can be taken. For example, although the flow rate calibration step is performed in the conditioning method, the flow rate calibration step may not be performed. By performing the seasoning process as described above, the flow rate of the WF₆ gas supplied into the plasma processing chamber 10 can be sufficiently close to the target flow rate.

Further, in the above-described embodiment, a plasma processing system is described in which a protective film of tungsten is formed on the mask film on the surface of the substrate W while plasma etching is performed. However, the plasma processing system may be configured to perform etching, ashing or the like as the plasma processing. Furthermore, the conditioning method may be executed not only at the time of start-up or maintenance of the apparatus, but also when the processing conditions for plasma processing the substrate W are changed.

The embodiments disclosed above include, for example, the following aspects.

[Clause 1] A method of conditioning a plasma processing chamber, which is configured such that a tungsten-containing gas is supplied into an inside of the plasma processing chamber and plasma processing is applied to a substrate housed in the inside of the plasma processing chamber, the method including:

(A) removing moisture from an inside of the plasma processing chamber using a gas free of the tungsten-containing gas; and

(B) adjusting an internal environment of the plasma processing chamber by generating plasma while supplying a gas containing the tungsten-containing gas after (A).

[Clause 2] The method according to clause 1, further including (C) calibrating a flow controller configured to control a flow of the tungsten-containing gas after (B).

[Clause 3] The method according to clause 1 or 2, wherein the tungsten-containing gas includes a WF6 gas, a WCl5 gas, or a WCl6 gas.

[Clause 4] The method according to clause 3, wherein in (B), a supply amount of the tungsten-containing gas is greater than a supply amount of the tungsten-containing gas used during the plasma processing of the substrate housed in the plasma processing chamber.

[Clause 5] The method according to any one of clauses 1 to 4, wherein in (A), a CF-containing gas and an O₂ gas are supplied as the gas free of the tungsten-containing gas.

[Clause 6] The method according to any one of clauses 1 to 5, wherein (A) includes repeatedly performing a process of generating the plasma while supplying the gas free of the tungsten-containing gas to the plasma processing chamber.

[Clause 7] The method of conditioning according to clause 6, wherein a number of times the process performed in (A) is set within a range from 30 to 50.

[Clause 8] The method of conditioning according to any one of clauses 1 to 7, wherein (B) includes repeatedly performing a process of generating the plasma while supplying the gas containing the tungsten-containing gas to the plasma processing chamber.

[Clause 9] The method of conditioning according to clause 8, wherein a number of times the process performed in (B) is set within a range from 30 to 60.

[Clause 10] A plasma processing system including:

a plasma processing chamber;

a gas supply configured to supply a tungsten-containing gas into an inside of the plasma processing chamber;

a power source configured to generate plasma by supplying electric power to the plasma processing chamber; and

a controller configured to control the gas supply and the power source,

wherein the controller is configured to control:

(A) removing moisture from the inside of the plasma processing chamber using a gas free of the tungsten-containing gas; and

(B) adjusting an internal environment of the plasma processing chamber by generating plasma while supplying a gas containing the tungsten-containing gas after (A).

The conditioning method and the plasma processing system according to the presently disclosed embodiments are exemplary. The present invention is not limited to these embodiments, and various variations and modifications may be made without departing from the scope of the present invention.

The plasma processing apparatus of the present disclosure is applicable to any type of apparatus: Atomic Layer Deposition (ALD) apparatus, Capacitively Coupled Plasma (CCP), Inductively Coupled Plasma (ICP), Radial Line Slot Antenna (RLSA), Electron Cyclotron Resonance Plasma (ECR), and Helicon Wave Plasma (HWP).

According to one aspect, plasma processing by supplying a tungsten-containing gas can be stably performed after maintenance, start-up of an apparatus, or the like.

What is claimed is:

1. A method of conditioning a plasma processing chamber, which is configured such that a tungsten-containing gas is supplied into an inside of the plasma processing chamber and plasma processing is applied to a substrate housed in the inside of the plasma processing chamber, the method comprising:
(A) removing moisture from an inside of the plasma processing chamber using a gas free of the tungsten-containing gas; and
(B) adjusting an internal environment of the plasma processing chamber by generating plasma while supplying a gas containing the tungsten-containing gas after (A).

2. The method according to claim 1, further comprising (C) calibrating a flow controller configured to control a flow of the tungsten-containing gas after (B).

3. The method according to claim 1, wherein the tungsten-containing gas includes a WF₆ gas, a WCl₅ gas, or a WCl₆ gas.

4. The method according to claim 3, wherein in (B), a supply amount of the tungsten-containing gas is greater than a supply amount of the tungsten-containing gas used during the plasma processing of the substrate housed in the plasma processing chamber.

5. The method according to claim 1, wherein in (A), a CF-containing gas and an O₂ gas are supplied as the gas free of the tungsten-containing gas.

6. The method according to claim 1, wherein (A) includes repeatedly performing a process of generating the plasma while supplying the gas free of the tungsten-containing gas to the plasma processing chamber.

7. The method according to claim 6, wherein a number of times the process performed in (A) is set within a range from 30 to 50.

8. The method according to claim 1, wherein (B) includes repeatedly performing a process of generating the plasma while supplying the gas containing the tungsten-containing gas to the plasma processing chamber.

9. The method according to claim 8, wherein a number of times the process performed in (B) is set within a range from 30 to 60.

10. A plasma processing system comprising:
a plasma processing chamber;
a gas supply configured to supply a tungsten-containing gas into an inside of the plasma processing chamber;
a power source configured to generate plasma by supplying electric power to the plasma processing chamber; and
a controller configured to control the gas supply and the power source,
wherein the controller is configured to control:
(A) removing moisture from the inside of the plasma processing chamber using a gas free of the tungsten-containing gas; and
(B) adjusting an internal environment of the plasma processing chamber by generating plasma while supplying a gas containing the tungsten-containing gas after (A).
